(19) United States
(12) Patent Application Publication
(10) Pub. No.: US 2008/0144279 A1
(43) Pub. Date: Jun. 19, 2008

(54) HEAT SINK

(75) Inventors: Tsutomu YAMAMOTO, Tokyo (JP); Yoshihisa HATOZAKI, Kobe City (JP)

Correspondence Address: ROSSI, KIMMS & McDOWELL LLP., P.O. BOX 826, ASHBURN, VA, 20146-0826, US

(73) Assignee: FUJI ELECTRIC FA COMPONENTS & SYSTEMS CO., LTD., Tokyo (JP)

(21) Appl. No.: 11/946,421

(22) Filed: Nov. 28, 2007

(30) Foreign Application Priority Data
Nov. 30, 2006 (JP) 2006-322724

(51) Int. Cl. H05K 7/20

(52) U.S. Cl. 361/694

(57) ABSTRACT

A heat sink is provided that makes air velocity between cooling fins uniform in order to improve heat dissipation performance, thereby realizing a reduction in weight and achieving high cost performance. Distal ends of fins disposed substantially in front of a cooling fan are located on the uppermost stream side in the flowing direction of cooling air, and distal ends of fins on both sides in the width direction of the heat sink are located on the lowermost stream side. Each of the fins is preferably provided with a slope so that the height of the fin gradually increases from the distal end thereof in a direction from the upstream side to the downstream side in the flowing direction of cooling air.

### BACKGROUND

The present invention relates to a heat sink that is air-cooled with forced air from a cooling fan, and more particularly to a heat sink for an inverter unit that converts alternating-current power supplied from a commercial power supply or the like into alternating-current power with a predetermined frequency and voltage and feeds the resultant power to an electric motor or the like.

FIG. 7 is a diagram showing a typical circuit configuration of an inverter unit of the above-mentioned type. The inverter unit 10 in FIG. 7 includes a converter 11 that rectifies alternating-current voltage supplied from a commercial power supply or the like via a terminal 19a of a terminal block 19 (see FIG. 8), an electrolytic capacitor 12 that smoothes the rectified voltage, an inverter 14 that converts the smoothed voltage across the electrolytic capacitor 12 into alternating-current voltage with a desired frequency that is output via a terminal 19b of the terminal block 19, a control circuit 15 that provides control signals to bring an IGBT and others constituting the inverter 14 to desired operating states, and a DC/DC converter 16 that serves as a power supply circuit that produces a gate power supply for the inverter 14 and a control power supply for the control circuit 15. In FIG. 7, reference numeral 13 denotes a resistance discharge circuit comprised of a damping resistor 13a, a transistor 13b, and so on for preventing the voltage across the electrolytic capacitor 12 from increasing to a predetermined value or greater due to regenerative electric power from loads of the inverter unit 10 or the like, and reference numeral 23 denotes a cooling fan that cools a heat sink 20, described later, that dissipates heat from heating components such as the converter 11 and the inverter 14.

FIG. 8 is a sectional view showing a conventional inverter apparatus having the inverter unit 10 in FIG. 7 incorporated therein. In FIG. 8, the heat sink 20 is constructed such that the heating components such as the converter 11 and the inverter 14 are disposed on one surface of a base 22, and a plurality of flat-shaped fins 21 are disposed on the other surface of the base 22. The cooling fan 23 circulates a cooling fluid by force, such as air, over the fins 21, so that the heat sink 20 dissipates heat generated from the heating components.

On the other hand, as shown in FIG. 8, the terminal block 19, the electrolytic capacitor 12, an insulating transformer 16a and an electrolytic capacitor 16b constituting the DC/DC converter 16, and so on are disposed on a component mounting surface (front side) of a main conversion circuit/power supply circuit board 17 inside a case 1. The converter 11 and the inverter 14 as main conversion circuits are disposed on the back side of the main conversion circuit/power supply circuit board 17, and one surface of each of the converter 11 and the inverter 14 is closely held on and fixed to a mounting surface of the base 22 of the heat sink 20. Further, the control circuit 15 appearing in FIG. 7 is disposed on a control circuit board 18, which is held by a case partition 2 secured to the case 1, so that heating of the main conversion circuit/power supply circuit board 17 is prevented from affecting the control circuit board 18.

The heat sink 20 used for the inverter unit 10 is often manufactured using a method called aluminum die-casting, particularly when a motor applied to the inverter unit 10 is small in capacity and size. As compared with a heat sink of a comb-like fin type manufactured by mounting an aluminum thin plate on a base surface through caulking or brazing, the heat sink 20 manufactured by aluminum die-casting has the advantage that it can function not only as a heat dissipation component but also as a mounting portion for mounting various components therein, i.e. as a case.

FIGS. 9 to 11 show the conventional heat sink 20 manufactured by aluminum die-casting, in which FIG. 9 is a perspective view showing the heat sink 20 as viewed from above, FIG. 10 is a perspective view showing the heat sink 20 as viewed from below, and FIG. 11 is a bottom view showing the heat sink 20. As shown in FIGS. 9 to 11, heating components such as the converter 11 and the inverter 14 are disposed on one surface of the base 22, a plurality of flat-shaped fins 21a to 21j are arranged substantially parallel at regular intervals on the other surface of the base 22, and the cooling fan 23 is provided on a cooling air inflow side. A space 24 for mounting therein components such as the damping resistor 13a is formed in a part of the heat sink 20. It should be noted that there are increasing cases where the height of the cooling fan 23 is set to be greater than that of the fins 21 as shown in FIGS. 8 to 10 due to a recent increasing demand for making inverter units compact.

In the conventional heat sink 20 for the inverter unit, to increase the heat dissipation surface area to a maximum extent, the fins 21 are arranged over substantially the entire base surface both in the width direction and the cooling air flowing direction except for the component mounting space 24. Specifically, as shown in FIGS. 10 and 11, the fins 21 are comprised of fins 21a to 21j having substantially the same length, and distal ends 50 of all the fins 21a to 21j on the cooling air inflow side (i.e. distal ends in the cooling air flowing direction) are located at the same distance from an end face 52 of the base 22.

Moreover, as disclosed in Japanese Laid-Open Patent Publication (Kokai) No. 2003-60135, there may be a case where distal ends of respective fins are arranged in a staggered configuration so as to decrease draft resistance of cooling air flowing between the fins of a heat sink.

FIG. 12 is a diagram showing an example of the air-velocity distribution between the fins 21a to 21j of the conventional heat sink 20 in a case where the air-velocity distribution of cooling air flowing in flow paths A to K between the fins 21a to 21j as indicated by arrows in FIG. 11 is measured.

As shown in FIG. 12, while the cooling fan 23 blows the cooling air on the fins 21a to 21j , the cooling air is less likely to blow on the fins located on both sides in the width direction of the heat sink, and hence the air velocity of the cooling air between the fins located on both sides in the width direction decreases. In addition, when the height of the cooling fan 23 is greater than that of the fins 21, the rotational direction of the cooling fan 23 affects the air-velocity distribution of the fins 21. For example, when the cooling fan 23 rotates in a direction indicated by the arrow α in FIG. 10, the air velocity is particularly low in the flow paths located on the delay side in the rotational direction of the cooling fan 23 (i.e. the flow paths J and K in FIGS. 11 and 12) due to a swirl flow produced through the rotation of the cooling fan 23.

It is a matter of course that, in heat sinks, the rate of heat transfer from the surfaces of fins decreases as the air velocity decreases. Thus, due to unevenness in air velocity, the conventional heat sinks cannot always achieve high heat dissipation performance although they have large surface areas. Moreover, in a case where the heat sinks are manufactured by aluminum die-casting, they are mass-produced using dies, and hence the manufacturing cost of the heat sinks is determined mainly by the weight of an aluminum material. Thus, the conventional heat sinks have the problem that cooling performance is not high relative to the cost if fins having the same lengths are disposed on the base surface.

### SUMMARY OF THE INVENTION

The present invention has been developed in view of the above described circumstances and provides a heat sink that can make the velocity of air between fins uniform to improve heat dissipation performance, thereby realizing a reduction in weight and achieving high cost performance.

Specifically, a heat sink is provided that includes a base with a first base end face and a second base end face, and a plurality of fins arranged on a surface of the base. The distal ends of the fins are arranged on the surface of the base so that the distal ends of the fins outside a central area of the first base end face are located further from the first base end face than the distal ends of the fins located in the central area of the first base end face. Preferably, the further the distance from the central area, the further the distal ends of the fins outside the central area are located from the first base end face.

In a preferred embodiment, at least some of the fins, or most preferably all of the fins, are provided with a slope so that a height of the fin from the surface of the base increases in a direction from the first base end face to the second base end face.

A cooling fan may be located adjacent the first base end face. In such a case, it is preferable that at least some of the distal ends of the fins on an advance side in a rotational direction of the cooling fan are located downstream of some of the distal ends of the fins on a delay side in the rotational direction of the cooling fan.

According to the present invention, since the distal ends of the fins in the flowing direction of cooling air are arranged so that the distal ends of the fins which are not located in the vicinity of the cooling fan are located downstream of the distal ends of the fins located in the vicinity of the cooling fan, the air-velocity distribution between the fins can be made uniform, so that cooling efficiency for the fins can be improved as a whole, and the heat sink having high cooling performance per unit weight can be realized.

Further, since the distal ends of the fins on the advance side in the rotational direction of the cooling fan are located downstream of the distal ends of the fins on the delay side in the rotational direction of the cooling fan, the air velocity on the delay side in the rotational direction of the cooling fan can be increased, making the air-velocity distribution between the fins more uniform, so that the cooing performance of the heat sink per unit weight can be further improved.

The above and other objects, features, and advantages of the invention will become more apparent from the following detailed description taken in conjunction with the accompanying drawings.

### BRIEF DESCRIPTION OF THE DRAWINGS

The invention will be described with reference to certain preferred embodiments thereof and the accompanying drawings, wherein:

FIG. 1 is a perspective view showing a heat sink according to a first embodiment of the present invention;

FIG. 2 is a bottom view showing the heat sink according to the first embodiment;

FIG. 3 is a diagram showing an example of the air-velocity distribution between fins in the heat sink according to the first embodiment;

FIG. 4 is a perspective view showing a heat sink according to a second embodiment of the present invention;

FIG. 5 is a bottom view showing the heat sink according to the second embodiment;

FIG. 6 is a diagram showing an example of the air-velocity distribution between fins in the heat sink according to the second embodiment;

FIG. 7 is a diagram showing the circuit configuration of an inverter unit;

FIG. 8 is a sectional view showing a conventional inverter apparatus;

FIG. 9 is a perspective view showing a conventional heat sink as viewed from above;

FIG. 10 is a perspective view showing the conventional heat sink as viewed from below;

FIG. 11 is a bottom view showing the conventional heat sink; and

FIG. 12 is a diagram showing an example of the air-velocity distribution between fins in the conventional heat sink.

### DETAILED DESCRIPTION OF THE PREFERRED EMBODIMENTS

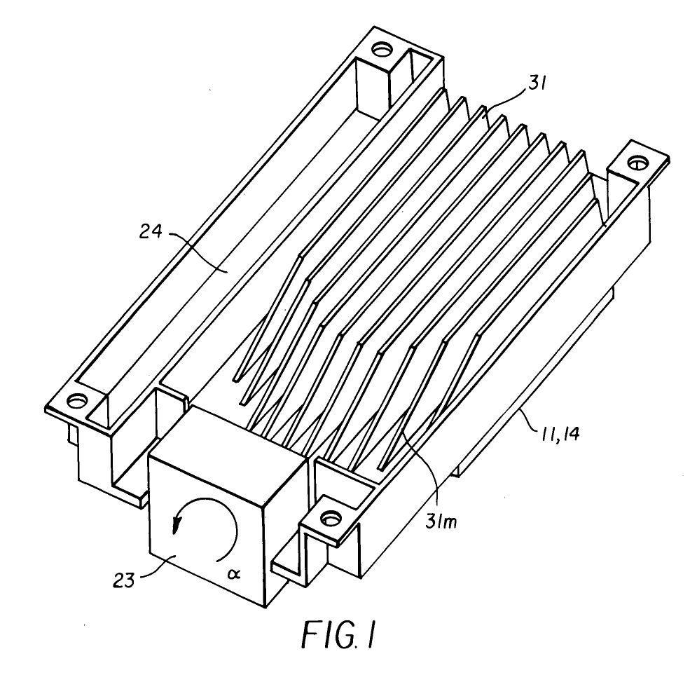

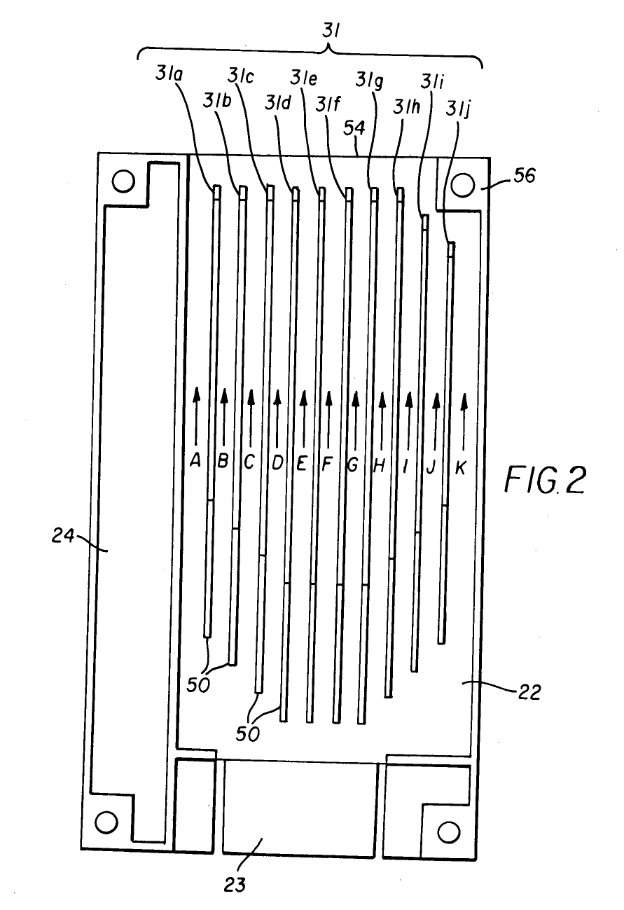

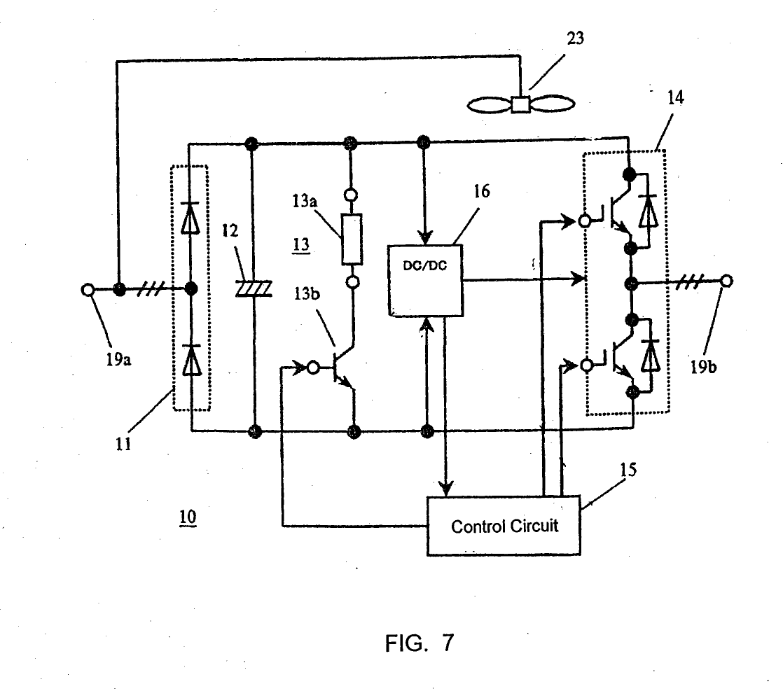

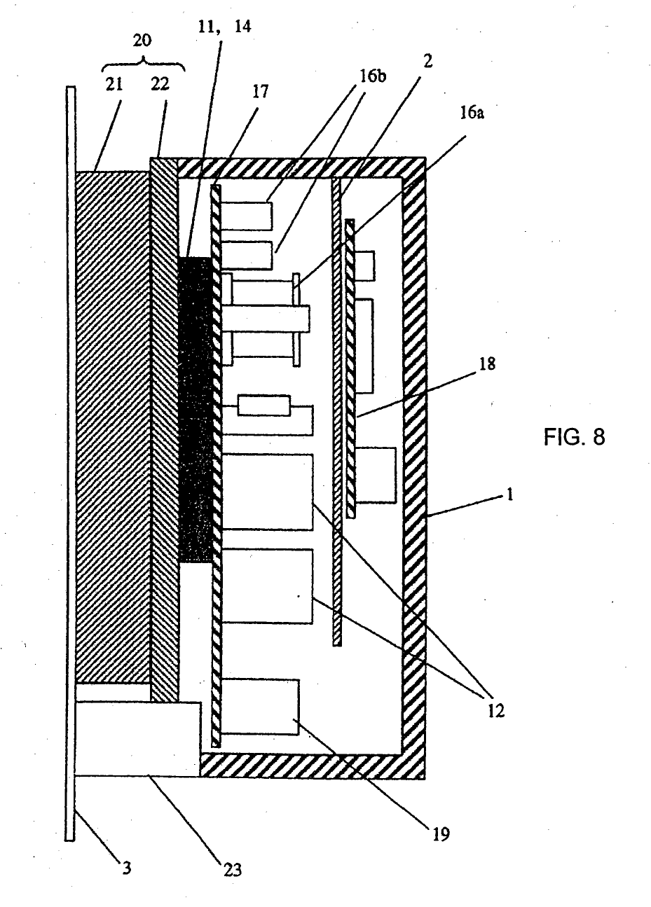

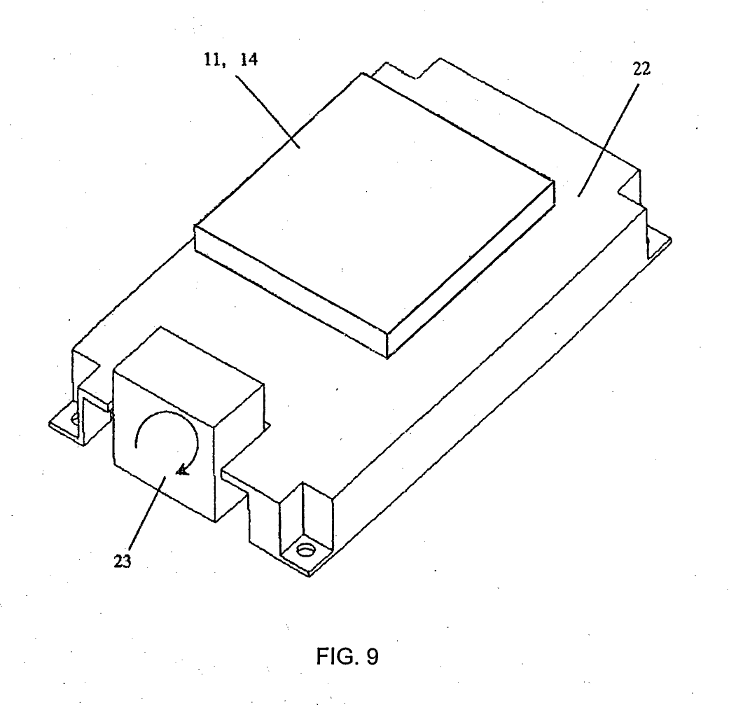

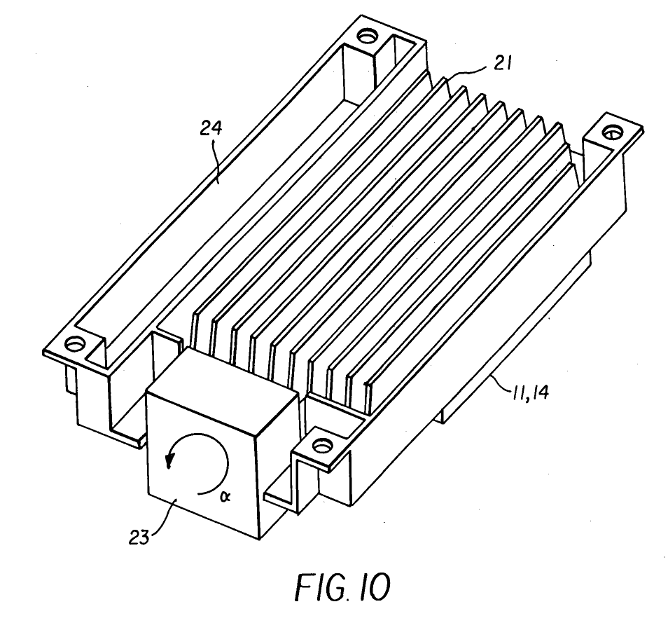

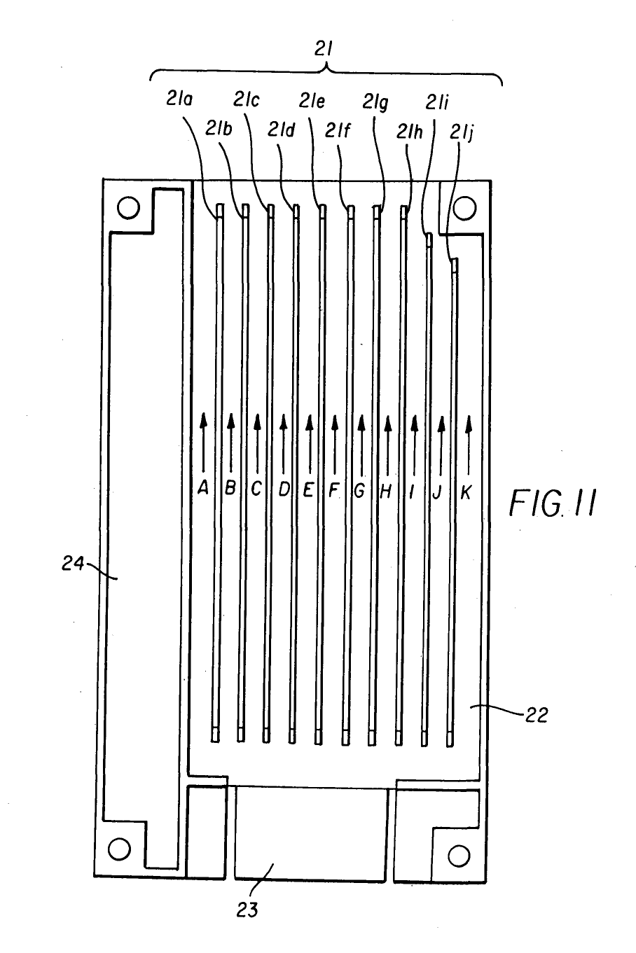

FIG. 1 is a perspective view showing a heat sink according to a first embodiment of the present invention, and FIG. 2 is a bottom view showing the heat sink according to the first embodiment. In FIGS. 1 and 2, the same members as those appearing in FIGS. 7 to 11 are denoted by the same reference numerals, and description thereof is omitted.

As shown in FIGS. 1 and 2, in the present embodiment, fins 31 are constructed such that the fins 31 disposed in the vicinity of the cooling fan 23 in a central area of the end face 52 (for example, fins 31d-31g) are longer in the cooling air flowing direction than the fins 31 which are not disposed in the vicinity of the cooling fan 23 in the central area (for example, fins 31a-31c and fins 31h-31j). Accordingly, the distal ends 50 of the fins 31 in the cooling air flowing direction are arranged such that the distal ends 50 of the fins 31 which are not disposed in the vicinity of the cooling fan 23 in the central area are located downstream (i.e., further from the based end face 52) of the distal ends 50 of the disposed in the vicinity of the cooling fan 23. That is, the longer the lateral distance from the cooling fan 23 or the central area of the base end face 52, the shorter the fins 31. Thus, the fins 31d to 31g located substantially in front of the cooling fan 23 are longest, and the fins 31a and 31j located on both sides in the width direction of the heat sink are shortest.

Further, the longer the distance from the cooling fan 23, the more downstream the distal ends 50 of the fins 31 are located in the cooling air flowing direction. Thus, the distal ends 50 of the fins 31d to 31g located substantially in front of the cooling fan 23 are located on the uppermost stream side (the distance from the inflow base end face 52 of the heat sink on the cooling air inflow side is short), and the distal ends of the fins 31a and 31j located on both sides in the width direction are located on the lowermost stream side (the distance from the inflow base end face 52 of the heat sink on the cooling air inflow side is long).

It should be noted that rear ends of the fins 31a to 31j in the cooling air flowing direction are substantially aligned (i.e. the rear ends of the fins 31a to 31j are located at substantially the same distances from an outflow base end face 54 of the heat sink on the cooling air outflow side). In the illustrated example, the rear ends of the fins 31i and 31j are slightly shorter due to the provision of a fastener portion 56 in the corner of the heat sink.

Further, each of the fins 31a to 31j s provided with a slope or inclined portion 31m so that the height of each fin from the base surface 22 gradually increases from the distal end 50 thereof in a direction from the upstream side to the downstream side in the cooling air flowing direction or from the inflow base end face 52 to the outflow base end face 54. It should be noted that the angle between the slope 31m and the base surface is preferably set to 30 to 60 degrees depending on the surface area needed to control a rise in the temperature of a heating component to within an allowable range, because the air velocity cannot be made uniform to a sufficient degree if the angle is approximately 90 degrees, and the fin surface area decreases if the angle is too small.

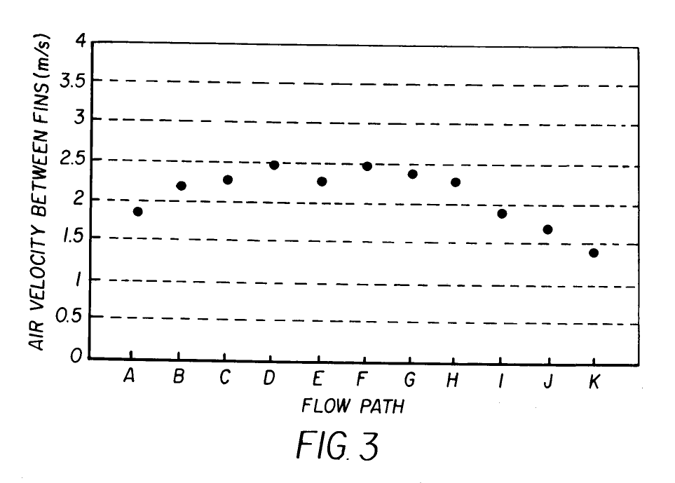

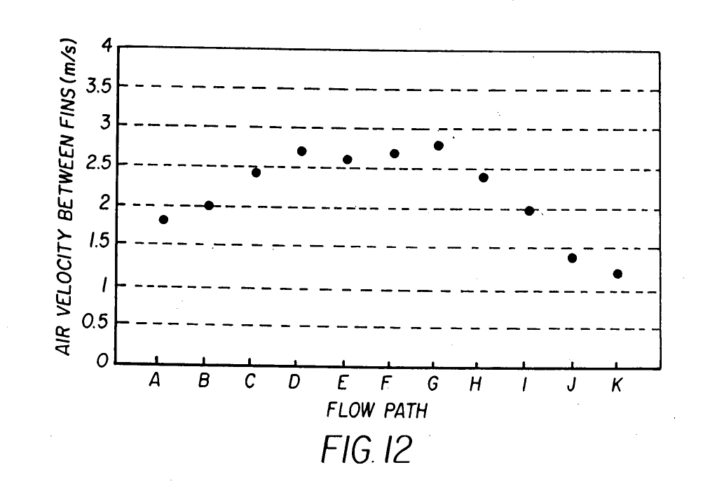

FIG. 3 is a diagram showing an example of the air-velocity distribution between the fins in the heat sink according to the first embodiment in a case where the air-velocity distribution of cooling air in flow paths A to K indicated by arrows between the fins 31a to 31j appearing in FIG. 2 is measured. As shown in FIG. 3, as compared with the air-velocity distribution in the conventional art illustrated in FIG. 12, the air velocity can be made more uniform, and the average air velocity can be made higher.

One of the reasons why the air velocity can be made more uniform is that pressure loss is reduced because the fins 31a to 31c and 31h to 31j, which are not located in the vicinity of the cooling fan 23, are made shorter, and their distal ends 50 are located further downstream or away from the inflow end face 52. Another reason why the air velocity can be made uniform is that the fins 31 are provided with the slopes 31m so that the height of each fin 31 from the base surface gradually increases from the upstream side to the downstream side in the cooling air flowing direction, and thus in a space between the cooling fan 23 and the fins 31, the movement of cooling air flowing out of the cooling fan 23 in the width direction of the heat sink can be facilitated.

Here, without forming the slopes 31m in the fins 31 as in the present invention, the movement of cooling air in the width direction of the heat sink may be facilitated by reducing the lengths of the fins 31 themselves in the cooling air flowing direction and increasing the distance between the fins 31 and the cooling fan 23. In general, however, heat dissipation performance deteriorates as the height of fins from the base surface increases, and hence for the same surface area, higher heat dissipation performance of the heat sink can be achieved by forming slopes in the fins as in the present invention.

It should be noted that the rate of heat transfer caused by forced convection is proportional to 0.5th to 0.8th power of air velocity, and if heat is dissipated almost uniformly from the entire base surface, the heat dissipation performance of the heat sink is higher in a case where the air velocity is uniformly distributed than in a case where the air velocity is not uniformly distributed. For this reason, in the heat sink in which the air velocity of cooling air flowing between the fins is made uniform as in the present embodiment, the average heat transfer rate on the surfaces of the fins, i.e. the amount of heat discharge per unit area increases, and hence the surface area, i.e. the weight need to control a rise in the temperature of heating components such as the converter 11 and the inverter 14 comprised of power modules to within an allowable range can be reduced.

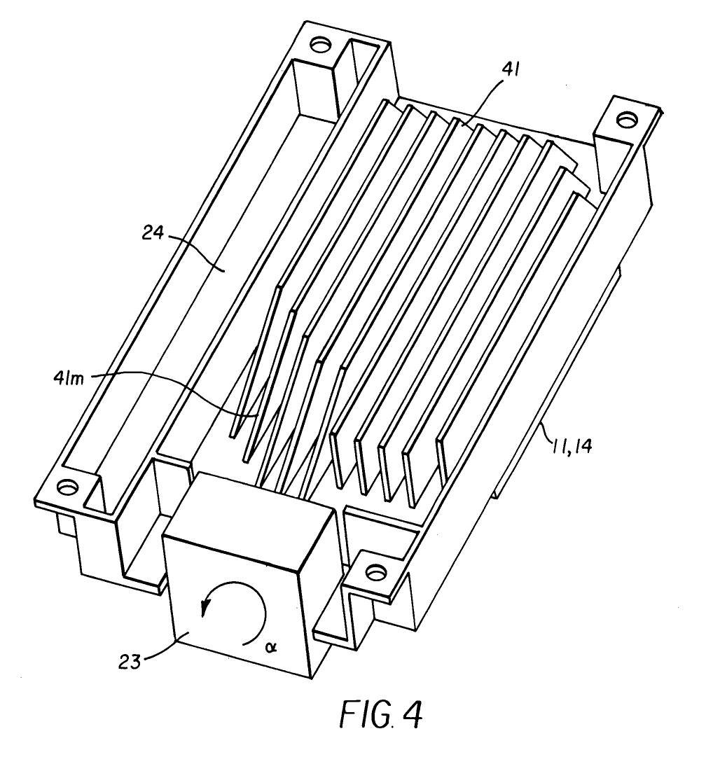

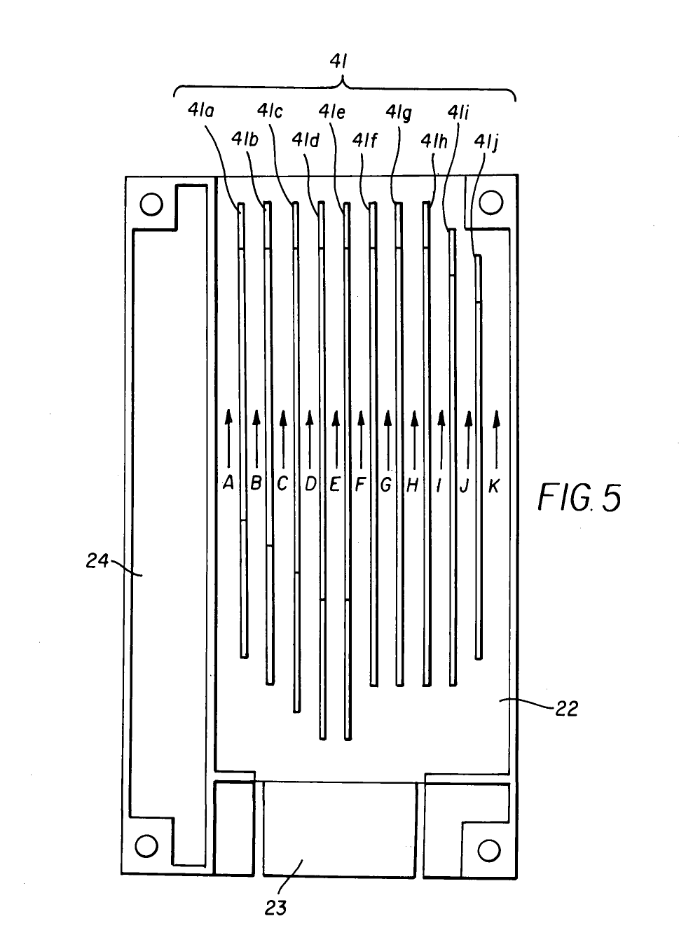

FIG. 4 is a perspective view showing a heat sink according to a second embodiment of the present invention, and FIG. 5 is a bottom view showing the heat sink according to the second embodiment. In FIGS. 4 and 5, the same members as those in the first embodiment described above are denoted by the same reference numerals, and description thereof is omitted.

In the second embodiment illustrated in FIGS. 4 and 5, fins 41 located on the delay side in the rotational direction of the cooling fan 23 (right side as viewed in FIG. 5) (as indicated by the arrow α) are formed to be shorter than fins 41 located on the advance side in the rotational direction of the cooling fan 23 (left side as viewed in FIG. 5), and distal ends of fins 41f to 41j on the delay side in the rotational direction of the cooling fan 23 are located downstream of distal ends of fins 41a to 41e on the advance side in the rotational direction of the cooling fan 23.

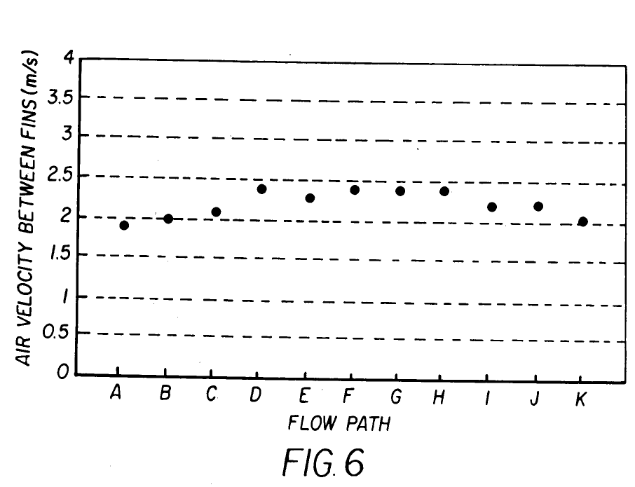

FIG. 6 is a diagram showing an example of the air-velocity distribution between the fins in the heat sink according to the second embodiment in a case where the air-velocity distribution of cooling air in flow paths A to K indicated by arrows between the fins 41a to 41j appearing in FIG. 5 is measured. As shown in FIG. 5, as compared with the air-velocity distribution in FIG. 3, the air velocity in the flow paths J and K is made higher, and the air velocity is made more uniform. For this reason, in the heat sink according to the second embodiment, the amount of heat discharge per unit area is larger than in the heat sink according to the first embodiment, and hence the surface area, i.e. the weight need to control a rise in the temperature of the power modules to within an allowable range can be further reduced.

As shown in FIGS. 4 and 5, each of the fins 41a to 41e located on the advance side in the rotational direction of the cooling fan 23 is provided with a slope 41 m so that the height of each of the fins 41a to 41e from the base surface increases from the distal end thereof in a direction from the upstream side to the downstream side in the cooling air flowing direction, whereas the fins 41f to 41j located on the delay side in the rotational direction of the cooling fan 23 are provided with no slopes. This is because, even if the fins 41f to 41f are provided with no slopes, the air velocity can be made substantially uniform as shown in FIG. 6, and hence, to make the surface area of the fins 41a to 41j large, the distal ends thereof are made substantially vertical to the base surface. Of course, each of the fins 41f to 41j located on the delay side in the rotational direction of the cooling fan 23 may be provided with the slope 41m. In the case where the fins 41f to 41j are provided with the slope 41m, the air velocity of cooling air flowing between the fins 41f to 41j located on the delay side in the rotational direction of the cooling fan 23 can be further increased, and also the weight of the heat sink can be further reduced.

The invention has been described with reference to certain preferred embodiments thereof. It will be understood, however, that modifications and variations are possible within the scope of the appended claims. For example, while the invention was described with manufacturing the heat sink from die cast aluminum, the invention is applicable to a heat sink structure formed from any type of manufacturing process including machining or milling.

What is claimed is:

1. A heat sink comprising:
a base including a first base end face and a second base end face; and
a plurality of fins arranged on a surface of the base;
wherein distal ends of the fins are arranged on the surface of the base so that the distal ends of the fins outside a central area of the first base end face are located further from the first base end face than the distal ends of the fins located in the central area of the first base end face.

2. A heat sink according to claim 1, wherein at least some of the fins are provided with a slope so that a height of the fin from the surface of the base increases in a direction from the first base end face to the second base end face.

3. A heat sink according to claim 1, wherein further the distance from the central area, the further the distal ends of the fins outside the central area are located from the first base end face.

4. A heat sink according to claim 1, further comprising a cooling fan located adjacent the first base end face.

5. A heat sink according to claim 4, wherein at least some of the distal ends of the fins on a delay side in a rotational direction of the cooling fan are located downstream of some of the distal ends of the fins on an advance side in the rotational direction of the cooling fan.

6. A heat sink according to claim 2, wherein all of the fins are provided with the slope.

7. A heat sink according to claim 1, wherein the fins are substantially flat-shaped fins and are arranged substantially parallel at regular intervals on the surface of the base.

8. A heat sink according to claim 1, wherein rear ends of the fins are located at substantially the same distance from the second base end face.

9. A heat sink according to claim 2, wherein an angle between the slope and the surface of the base is from 30 to 60 degrees.

10. A heat sink according to claim 1, further comprising a component mounting space provided on the surface of the base.
